(19) United States
(12) Patent Application Publication
(10) Pub. No.: US 2024/0060171 A1
(43) Pub. Date: Feb. 22, 2024

(54) SURFACE TREATMENT APPARATUS AND SURFACE TREATMENT METHOD

(71) Applicant: Shibaura Machine Co., Ltd., Tokyo (JP)

(72) Inventors: Kazuhiro FUKADA, Numazu-shi (JP); Satoshi FUKUYAMA, Numazu-shi (JP); Mitsunori KOKUBO, Numazu-shi (JP); Takeshi NAMBA, Sunto-gun (JP)

(73) Assignee: Shibaura Machine Co., Ltd., Tokyo (JP)

(21) Appl. No.: 18/259,885

(22) PCT Filed: Dec. 28, 2021
(86) PCT No.: PCT/JP2021/048784

§ 371 Date: Jun. 29, 2023

(30) Foreign Application Priority Data
Jan. 19, 2021 (JP) 2021-006533

(51) Int. Cl. C23C 14/34; C23C 14/50; C23C 14/54; C23C 14/56

(52) U.S. Cl. CPC C23C 14/34; C23C 14/505; C23C 14/545; C23C 14/56

(57) ABSTRACT

A surface treatment apparatus includes a mounting device, a housing unit, a surface treatment device, a conveyance device, and a first adjustment device. A workpiece is mounted on the mounting device. The housing unit houses the workpiece mounted on the mounting device. The surface treatment device performs at least one kind of surface treatment on the workpiece housed in the housing unit. The conveyance device conveys the workpiece mounted on the mounting device along the surface treatment device. The first adjustment device adjusts an orientation of the workpiece according to a conveyance position by the conveyance device and a position of the surface treatment device.

### TECHNICAL FIELD

The present invention relates to a surface treatment apparatus and a surface treatment method that performs surface treatment on a workpiece.

### BACKGROUND ART

Thus far, a surface treatment apparatus that forms a metal catalyst layer, a SiOx film, or the like by using plasma to clean or modify a surface of a workpiece and a surface treatment apparatus that forms a thin film on a surface of a workpiece by using a sputtering apparatus have been known.

For example, in a film formation apparatus described in Patent Literature 1, a plurality of substrates set on a carriage are conveyed to the interior of the film formation apparatus, and necessary surface treatment is performed. As an example of surface treatment, plasma treatment described in Patent Literature 2 is known.

### CITATION LIST

### Patent Literature

Patent Literature 1: JP H4-231464 A
Patent Literature 2: WO 2017/159838 A

### SUMMARY OF INVENTION

### Problem to be Solved by the Invention

The film formation apparatus of Patent Literature 1 has a structure suitable for performing surface treatment of a large amount of workpieces and has a large scale, and thus is not suitable for small-scale production to medium-scale production. Further, when performing surface treatment of a workpiece, it is desirable that different kinds of surface treatment such as sputtering and plasma treatment described in Patent Literature 2 be allowed to be performed by one apparatus.

The present invention has been made in view of the above, and an object of the present invention is to provide a surface treatment apparatus and a surface treatment method suitable for performing surface treatment of a small amount to a medium amount of material.

### Means for Solving Problem

In order to solve the above problem and achieve the object, a surface treatment apparatus according to the present invention includes: a mounting device on which a workpiece is mounted; a housing unit that houses the workpiece mounted on the mounting device; a surface treatment device that performs at least one kind of surface treatment on the workpiece housed in the housing unit; a conveyance device that conveys the workpiece mounted on the mounting device along the surface treatment device; and a first adjustment device that adjusts an orientation of the workpiece according to a conveyance position by the conveyance device and a position of the surface treatment device.

### Effect of the Invention

A surface treatment apparatus according to the present invention has an effect of being suitable for performing surface treatment of a small amount to a medium amount of workpieces.

### BRIEF DESCRIPTION OF DRAWINGS

FIG. 1 is a diagram of a rough configuration of a surface treatment apparatus of a first embodiment;

FIG. 2 is a top view of the interior of a chamber of the surface treatment apparatus of the first embodiment;

FIG. 3 is an exploded perspective view illustrating a workpiece attachment structure;

FIG. 4 is a cross-sectional view illustrating a workpiece attachment structure;

FIG. 5 is a front view describing a mechanism of adjusting the orientation of a workpiece;

FIG. 6 is a side view describing the mechanism of adjusting the orientation of a workpiece;

FIG. 7 is a top view describing the mechanism of adjusting the orientation of a workpiece;

FIG. 8 is a diagram describing a method for adjusting the inclination in the height direction of a workpiece;

FIG. 9 is a diagram describing how the orientation of a workpiece is adjusted when performing surface treatment;

FIG. 10 is a cross-sectional view illustrating an example of a structure of an HCD electrode;

FIG. 11 is a cross-sectional view illustrating an example of a structure of a sputtering electrode;

FIG. 12 is a diagram illustrating an example of surface treatment performed on a workpiece by the surface treatment apparatus;

FIG. 13 is a diagram illustrating an example of pressure change in a chamber when the surface treatment apparatus performs surface treatment on a workpiece;

FIG. 14 is a flowchart illustrating an example of a flow of processing performed when the surface treatment apparatus performs surface treatment on a workpiece;

FIG. 15 is an exploded perspective view illustrating a workpiece attachment structure;

FIG. 16 is a cross-sectional view illustrating an example of a state where a workpiece is sandwiched between a bedplate and a base material holder;

FIG. 17 is a diagram describing in more detail a method for adjusting the inclination in the height direction of a workpiece;

FIG. 18 is a flowchart illustrating an example of a flow of processing of adjusting the inclination in the height direction of a workpiece;

FIG. 19 is a top view of the interior of a chamber of a surface treatment apparatus of a second embodiment;

FIG. 20 is an exploded perspective view illustrating a workpiece attachment structure in the surface treatment apparatus of the second embodiment; and

FIG. 21 is a cross-sectional view illustrating a workpiece attachment structure in the surface treatment apparatus of the second embodiment.

### DESCRIPTION OF EMBODIMENTS

Hereinbelow, embodiments of a surface treatment apparatus according to the present disclosure are described in detail based on the drawings. Note that this invention is not limited by the embodiments. In addition, constituent elements in the following embodiments include those that can be substituted and can be easily conceived by those skilled in the art, or those that are substantially the same.

### 1. First Embodiment

A first embodiment of the present disclosure is an example of a surface treatment apparatus 10 that performs surface treatment on a surface of a workpiece W having a large area of about 500×600 mm, which is molded with a resin material such as a plastic resin, for example. More specifically, the surface treatment apparatus 10 performs sputtering to generate an Al layer that is a thin film of aluminum (Al) on the surface of the workpiece W. After that, the surface treatment apparatus 10 irradiates the Al layer with plasma to generate a SiOx film on the surface of the workpiece W. The surface of the workpiece W on which a SiOx film is generated has improved environment resistance. Further, with the surface treatment apparatus 10, the surface of the workpiece W may be irradiated with oxygen plasma, and a material such as copper, which serves as a plating seed layer, may be generated by sputtering; thereby, the adhesion of a thin film that serves as an underlayer at the time of plating processing in a subsequent step is improved.

[1-1. Description of Overall Configuration of Surface Treatment Apparatus]

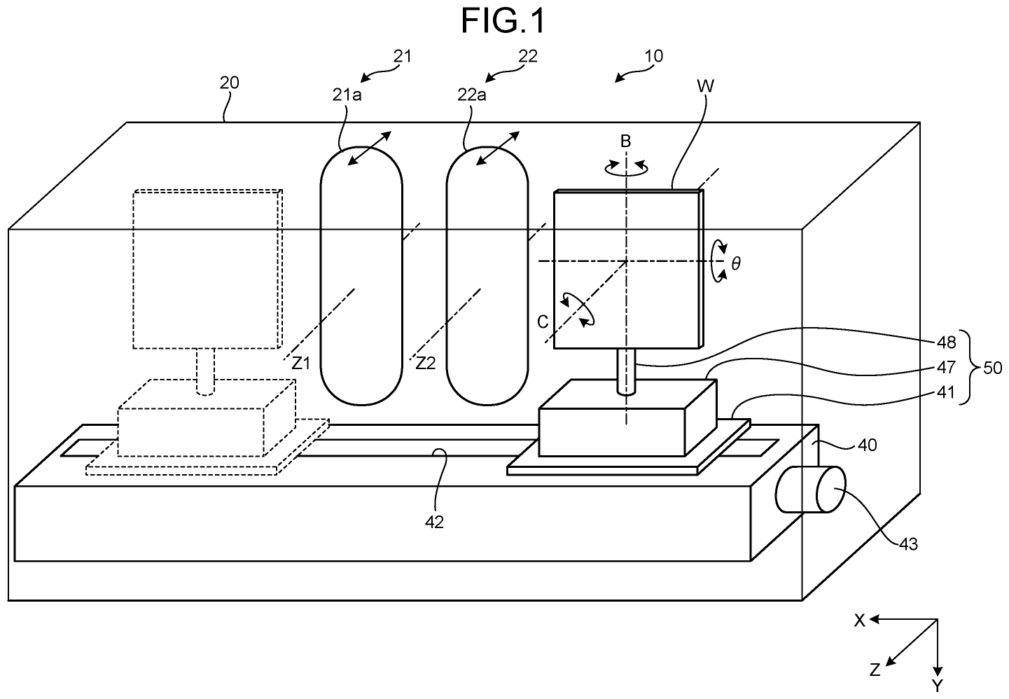

First, a rough structure of the surface treatment apparatus 10 is described using FIG. 1. FIG. 1 is a diagram of a rough configuration of a surface treatment apparatus of the first embodiment.

As illustrated in FIG. 1, the surface treatment apparatus 10 includes a workpiece mounting unit 50, a workpiece conveyance unit 40, a HCD (hollow cathode discharge) electrode 21a, and a sputtering electrode 22a, which are contained in a chamber 20.

The chamber 20 is a sealed reaction vessel that performs surface treatment on a workpiece W housed therein. The chamber 20 has a rectangular parallelepiped shape of which the longitudinal direction is the X-axis direction in the XYZ coordinate system illustrated in FIG. 1. The chamber 20 is an example of a housing unit in the present disclosure.

The workpiece mounting unit 50 has the workpiece W mounted thereon in a state where the workpiece W is set to substantially stand along the Y-axis direction. The workpiece mounting unit 50 is an example of a mounting device in the present disclosure. The workpiece mounting unit 50 includes a moving stage 41, an attachment stage 47, and an attachment shaft 48.

The moving stage 41 is a pedestal on which the workpiece W is placed. The moving stage 41 is conveyed along the X-axis by the workpiece conveyance unit 40 described later. The moving stage 41 is an example of a pedestal member in the present disclosure.

The attachment stage 47 is a member that is installed on the moving stage 41 and serves as a base to which the workpiece W is attached. The attachment stage 47 is an example of a base member in the present disclosure.

The attachment shaft 48 supports the workpiece W on the attachment stage 47. The attachment shaft 48 is an example of a support member in the present disclosure.

The workpiece conveyance unit 40 conveys the workpiece W mounted on the workpiece mounting unit 50 along the longitudinal direction of the chamber 20 (the X-axis). The workpiece conveyance unit 40 is an example of a conveyance device in the present disclosure.

The workpiece conveyance unit 40 is a single-axis moving table driven by a conveyance motor 43. Specifically, the workpiece conveyance unit 40 moves the workpiece mounting unit 50 installed on the moving stage 41 along a groove 42. The moving stage 41 is an example of a pedestal member in the present disclosure. The configuration of the workpiece conveyance unit 40 is not limited to the example illustrated in FIG. 1. For example, it may be a belt conveyor type.

The sputtering electrode 22a is an electrode of a sputtering apparatus 22, which is an example of a surface treatment device in the present disclosure. The sputtering apparatus 22 performs sputtering by ejecting atoms used for film formation from a target placed on the sputtering electrode 22a and causing the ejected atoms to adhere to the surface of the workpiece W. By sputtering, for example, a thin film serving as an underlayer of plating processing is formed on the surface of the workpiece W. The width (the length in the X-axis direction) of the sputtering electrode 22a is shorter than the width (the length in the X-axis direction) of the workpiece W. The sputtering electrode 22a is an example of an electrode in the present disclosure.

The HCD electrode 21a is an electrode of a plasma generation apparatus 21, which is an example of a surface treatment device in the present disclosure. The plasma generation apparatus 21 applies plasma generated by the HCD electrode 21a to the workpiece W on which a thin film is formed by the sputtering apparatus 22 and thereby performs surface treatment of the workpiece W, and generates, for example, a SiO₂ layer on the surface of the workpiece W. Thereby, the environment resistance of the surface of the workpiece W is improved. Further, the surface of the workpiece W may be irradiated with oxygen plasma generated by the HCD electrode 21a, and a material such as copper, which serves as a plating seed layer, may be generated by sputtering; thereby, the adhesion of a thin film that serves as an underlayer at the time of plating processing in a subsequent step is improved. The width (the length in the X-axis direction) of the HCD electrode 21a is shorter than the width (the length in the X-axis direction) of the workpiece W. The HCD electrode 21a is an example of an electrode in the present disclosure.

It is also possible to employ a configuration in which each of the HCD electrode 21a and the sputtering electrode 22a is divided into a plurality of regions along the Y-axis and the divided regions are controlled by different outputs. With such a configuration, a workpiece W with a large area can be more uniformly surface-treated.

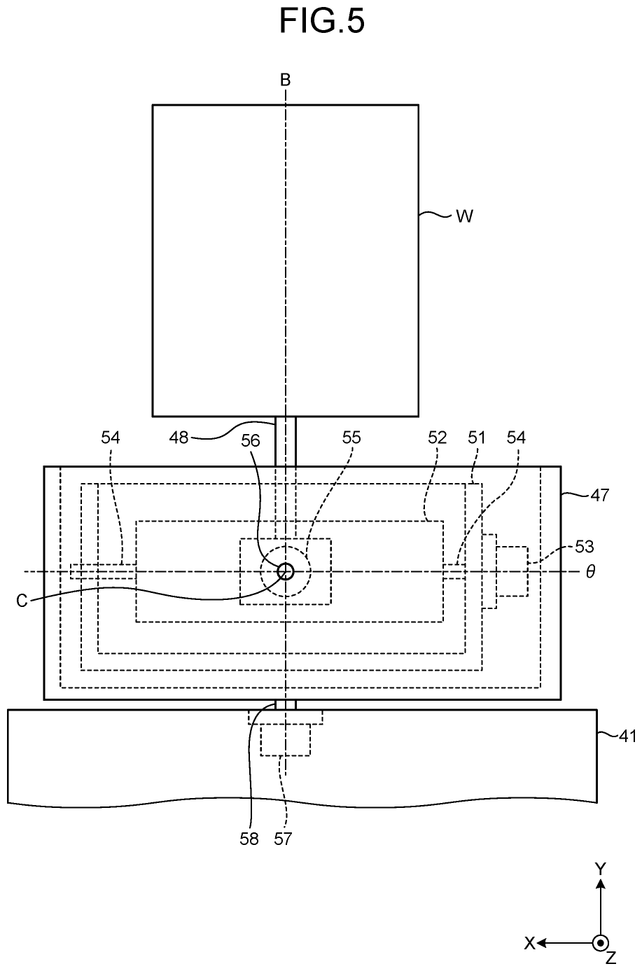

The workpiece mounting unit 50 includes a first adjustment device that adjusts the orientation of the workpiece W. More specifically, when performing surface treatment, the first adjustment device adjusts the orientation of the workpiece W around axis B illustrated in FIG. 1, that is, around an axis orthogonal to both the conveyance direction of the workpiece conveyance unit 40 and the normal direction of the sputtering electrode 22a included in the sputtering apparatus 22 or the normal direction of the HCD electrode 21a included in the plasma generation apparatus 21. More specifically, the first adjustment device adjusts the orientation of the workpiece W with respect to the sputtering electrode 22a or the HCD electrode 21a by swinging the workpiece W around axis B by an amount corresponding to the position in the X-axis direction of the workpiece W. Thereby, uniform film formation can be performed on the surface of a workpiece W with a large area. The position of axis B is not limited to the position illustrated in FIG. 1, and may be set to any position parallel to the Y-axis. The adjustment around axis B will be described in detail later (see FIGS. 5 to 7 and 9).

The first adjustment device further adjusts the orientation of the workpiece W around axis C illustrated in FIG. 1, that is, around the normal direction of the workpiece W. Thereby, uniform film formation can be performed on the surface of a workpiece W with a large area. The position of axis C is not limited to the position illustrated in FIG. 1, and may be set to any position parallel to the Z-axis. The adjustment around axis C will be described in detail later (see FIGS. 5 to 7).

The workpiece mounting unit 50 further includes a second adjustment device that adjusts the orientation of the workpiece W around axis θ illustrated in FIG. 1 to adjust the inclination in the height direction (the inclination with respect to the Y-axis) of the workpiece W to a predetermined value. Thereby, when the workpiece W has distortion, non-uniform film formation due to the distortion can be prevented. The position of axis θ is not limited to the position illustrated in FIG. 1, and may be set to any position parallel to the X-axis. The adjustment around axis θ will be described in detail later (see FIGS. 5 to 8).

The surface treatment apparatus 10 further includes an exhaust apparatus, a cooling apparatus, a control apparatus, a power supply apparatus, a gas supply apparatus, an operating panel, etc., but illustration thereof is omitted for simplicity of description.

The exhaust apparatus decompresses the interior of the chamber 20 into a vacuum state. The exhaust apparatus includes, for example, a rotary pump or a turbo molecular pump.

The cooling apparatus generates cooling water that cools equipment, a power source, etc.

The control apparatus controls the entire surface treatment apparatus 10.

The power supply apparatus accommodates power to be supplied to each unit of the surface treatment apparatus 10.

The gas supply apparatus supplies film formation gas and reaction gas to the chamber 20.

The operating panel accepts an operating instruction to the surface treatment apparatus 10. In addition, the operating panel has a function of displaying an operating state of the surface treatment apparatus 10.

Although the present embodiment describes an example in which the workpiece W is subjected to sputtering treatment and then to plasma treatment, the surface treatment apparatus 10 may subject the workpiece W to plasma treatment and then to sputtering treatment. Further, although in the present embodiment the surface treatment apparatus 10 includes two kinds of surface treatment device of the sputtering apparatus 22 and the plasma generation apparatus 21, it is sufficient that at least one kind of surface treatment device be provided.

[1-2. Description of Surface Treatment Performed by Surface Treatment Apparatus]

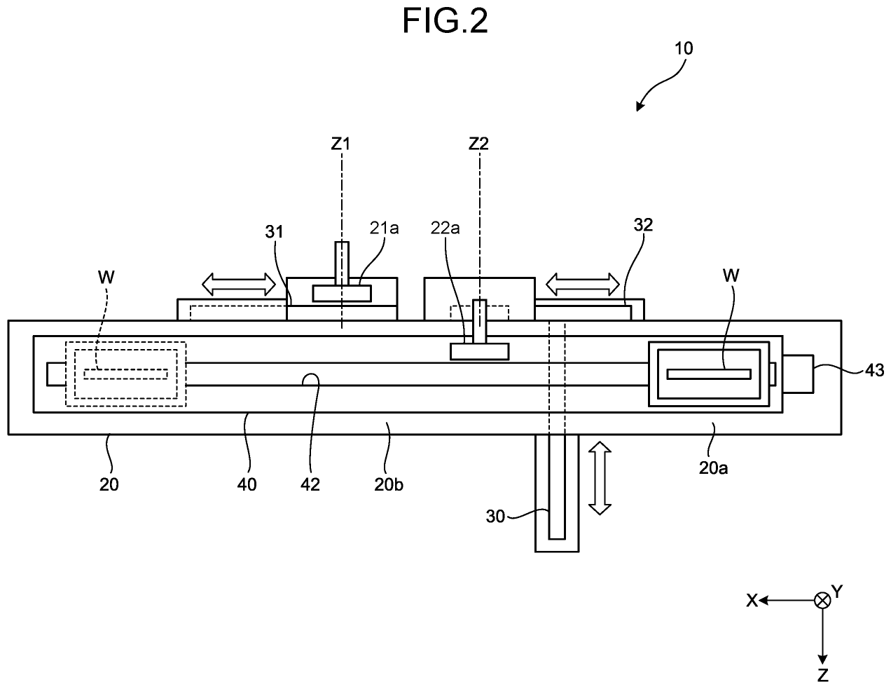

Next, a method of surface treatment performed by the surface treatment apparatus 10 is described using FIG. 2. FIG. 2 is a top view of the interior of the chamber of the surface treatment apparatus of the first embodiment.

The chamber 20 includes a shutter 30, a shutter 31, and a shutter 32.

The shutter 30 moves in the negative direction of the Z-axis to partition the interior of the chamber 20 into a load lock chamber 20a and a reaction chamber 20b. After the shutter 30 is closed and the workpiece W is mounted in the load lock chamber 20a, the interior of the load lock chamber 20a is set to low pressure to remove the atmospheric components adhering to the workpiece W. After that, the shutter 30 is opened to convey the workpiece W to the reaction chamber 20b, and surface treatment (film formation treatment) is performed. The shutters 30, 31, and 32 may also be opened or closed by a system in which standby positions of the shutters 30, 31, and 32 are provided above the chamber 20 and the shutters 30, 31, and 32 are moved along the Y-axis.

The shutter 31 moves in the positive direction of the X-axis to expose the HCD electrode 21a when performing plasma treatment on the workpiece W. Further, the shutter 31 moves in the negative direction of the X-axis to house the HCD electrode 21a when performing sputtering treatment on the workpiece W. Thereby, contamination of an electrode that is not used is prevented. The shutter 31 is an example of a shielding member in the present disclosure.

The shutter 32 moves in the negative direction of the X-axis to expose the sputtering electrode 22a when performing sputtering treatment on the workpiece W. Further, the shutter 32 moves in the positive direction of the X-axis to house the sputtering electrode 22a when performing plasma treatment on the workpiece W. Thereby, contamination of an electrode that is not used is prevented. The shutter 32 is an example of a shielding member in the present disclosure.

The HCD electrode 21a is set movable along axis Z1 parallel to the Z-axis. Thus, more uniform film formation treatment can be performed by setting the spacing between the workpiece W and the HCD electrode 210a to an optimum value.

The sputtering electrode 22a is set movable along axis Z2 parallel to the Z-axis. Thus, more uniform film formation treatment can be performed by setting the spacing between the workpiece W and the sputtering electrode 22a to an optimum value.

Although it is desirable that the HCD electrode 21a and the sputtering electrode 22a not be moved in the axis Z1 or axis Z2 direction during film formation, the delivery amount in the axis Z1 or axis Z2 direction may be appropriately changed according to values such as the degree of vacuum in the chamber 20, the gas flow rate, the conveyance speed of the workpiece W, the power, the voltage value, the current value, the discharge state, and the temperature in the chamber 20. Thereby, more uniform film formation treatment can be performed. Further, the conveyance speed of the workpiece W may be changed according to the values of the parameters mentioned above.

The workpiece W for which sputtering treatment and plasma treatment are completed moves to the position of the dotted lines indicated in FIG. 2. After that, the workpiece W is moved to a position in the load lock chamber 20a. Then, the shutter 30 is closed, the pressure of the interior of the load lock chamber 20a is increased to atmospheric pressure, and then the workpiece W for which film formation treatment is completed is taken out from the chamber 20.

[1-3. Description of Workpiece Attachment Structure]

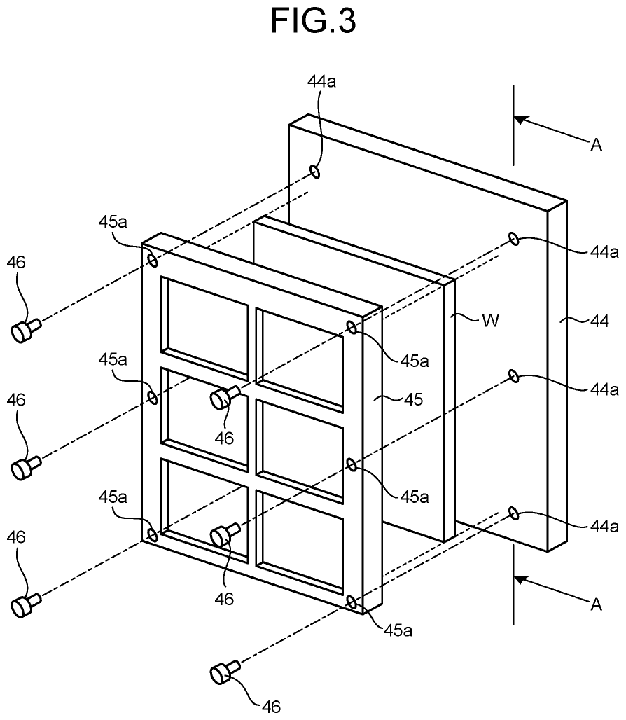

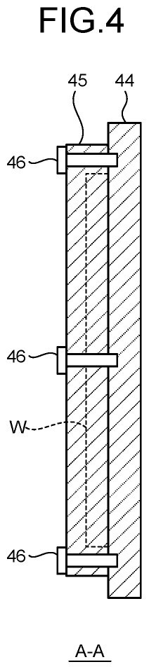

Next, a workpiece W attachment structure is described using FIGS. 3 and 4. FIG. 3 is an exploded perspective view illustrating a workpiece attachment structure. FIG. 4 is a cross-sectional view illustrating a workpiece attachment structure.

As illustrated in FIG. 3, a workpiece W is attached to the workpiece mounting unit 50 in a state where the workpiece W is sandwiched between a bedplate 44 and a base material holder 45.

The bedplate 44 is a plate-shaped member that is slightly larger than the workpiece W and holds the workpiece W in a state where the surface of the workpiece W on the side not subjected to surface treatment is kept in contact.

The base material holder 45 is a plate-shaped member formed in a grid shape. As illustrated in FIG. 4, the base material holder 45 has a thickness larger than the thickness of the workpiece W. The back surface side (the side in contact with the workpiece W) of the base material holder 45 is formed thin in accordance with the shape of the workpiece W, and reliably holds the workpiece W when the workpiece W is sandwiched between the base material holder 45 and the bedplate 44. Since the portion of the workpiece W in contact with the grid of the base material holder 45 is not subjected to surface treatment, the workpiece W for which surface treatment is completed is cut at the portion of the grid and used. Although a base material holder 45 having only an outer frame without a grid may be used, in the case of a workpiece W with a large area, residual stress may be generated in the workpiece W if the workpiece W is subjected to film formation treatment in a distorted state; thus, it is desirable that a base material holder 45 on which a grid is formed be used and the workpiece W be fixed in a state of being reliably pressed against the bedplate 44.

A plurality of attachment holes 45a through which screws 46 penetrate are formed in an outer edge portion of the base material holder 45. The screw 46 inserted into the attachment hole 45a is coupled with a female screw 44a formed in the bedplate 44 to fix the base material holder and the bedplate 44 in a state of sandwiching the workpiece W. The base material holder 45 and the bedplate 44 may be fixed using a one-touch clip or the like instead of the screw 46.

[1-4. Description of First Adjustment Device]

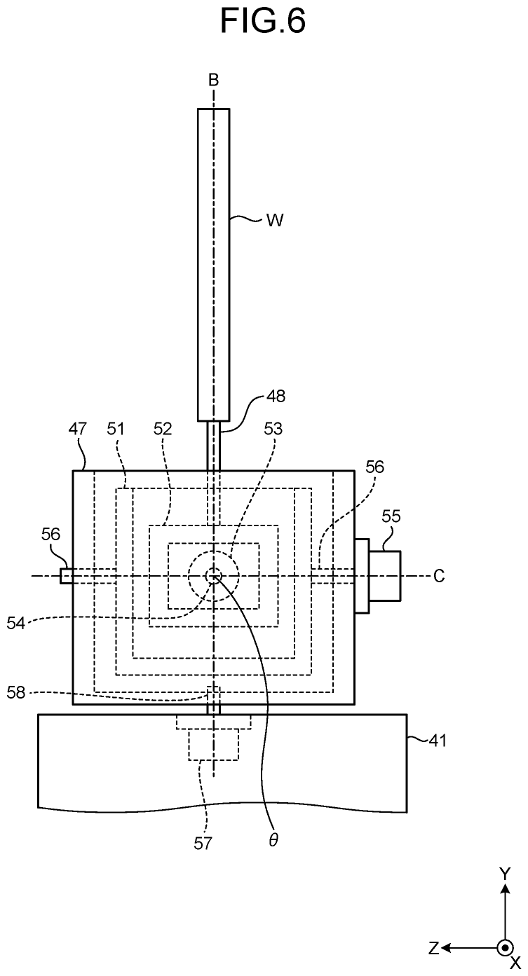

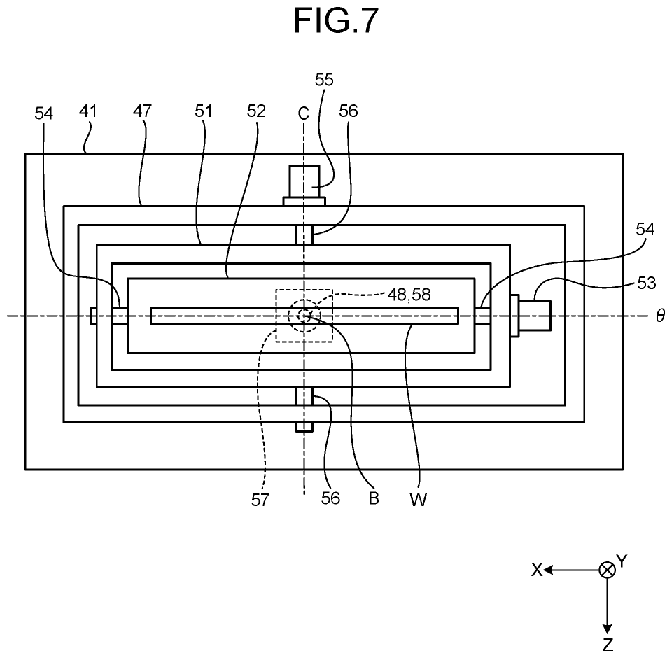

Next, a first adjustment device is described using FIGS. 5, 6, and 7. FIG. 5 is a front view describing a mechanism of adjusting the orientation of a workpiece. FIG. 6 is a side view describing the mechanism of adjusting the orientation of a workpiece. FIG. 7 is a top view describing the mechanism of adjusting the orientation of a workpiece. For easier description, FIGS. 5, 6, and 7 omit the bedplate 44 and the base material holder 45 described above.

As illustrated in FIGS. 5 to 7, a C-axis rotation stage 51 and a θ-axis rotation stage 52 are installed in the interior of the attachment stage 47. The C-axis rotation stage 51 is attached to the attachment stage 47 to be rotatable around axis C with respect to the attachment stage 47 by an attachment shaft 56. The C-axis rotation stage 51 rotates (swings) around axis C by the rotational driving force of a C-axis rotation motor 55. The C-axis rotation motor 55 is, for example, a step motor, a servomotor, or the like that can be instructed about the rotation angle from the outside. The C-axis rotation motor 55 is a motor that can be used in a vacuum environment. The C-axis rotation motor 55 is an example of a first adjustment device in the present disclosure.

The θ-axis rotation stage 52 is attached to the C-axis rotation stage 51 to be rotatable around axis θ with respect to the attachment stage 47 by an attachment shaft 54. The θ-axis rotation stage 52 rotates around axis θ by the rotational driving force of a θ-axis rotation motor 53. The θ-axis rotation motor 53 is, for example, a step motor, a servomotor, or the like that can be instructed about the rotation angle from the outside. The θ-axis rotation motor 53 is a motor that can be used in a vacuum environment. The θ-axis rotation motor 53 is an example of a second adjustment device in the present disclosure.

As illustrated in FIGS. 5 to 7, the attachment stage 47 is attached to the moving stage 41 to be rotatable around axis B with respect to the moving stage 41 by an attachment shaft 58. The attachment stage 47 rotates around axis B by the rotational driving force of a B-axis rotation motor 57. In other words, the attachment stage 47 is a B-axis rotation stage. The B-axis rotation motor 57 is, for example, a step motor, a servomotor, or the like that can be instructed about the rotation angle from the outside. The B-axis rotation motor 57 is a motor that can be used in a vacuum environment. The B-axis rotation motor 57 is an example of a first adjustment device in the present disclosure.

The configurations of the rotation mechanisms around axis B, axis C, and axis θ and the conveyance mechanism in the X-axis direction are not limited to the examples illustrated in FIGS. 1 and 5 to 7. For example, the workpiece W can be rotated around axis C without using a motor. That is, translational motion in the X-axis direction of the moving stage 41 may be converted into rotational motion of a pinion gear by a rack-and-pinion mechanism, and the rotational motion may be transmitted to the workpiece W via a floating joint. With such a configuration, the workpiece W can be rotated around axis C without using a motor. In this case, the rotation rate of the workpiece W around axis C is determined by the gear ratio of the rack and pinion and the conveyance speed in the X-axis direction.

[1-5. Description of Second Adjustment Device]

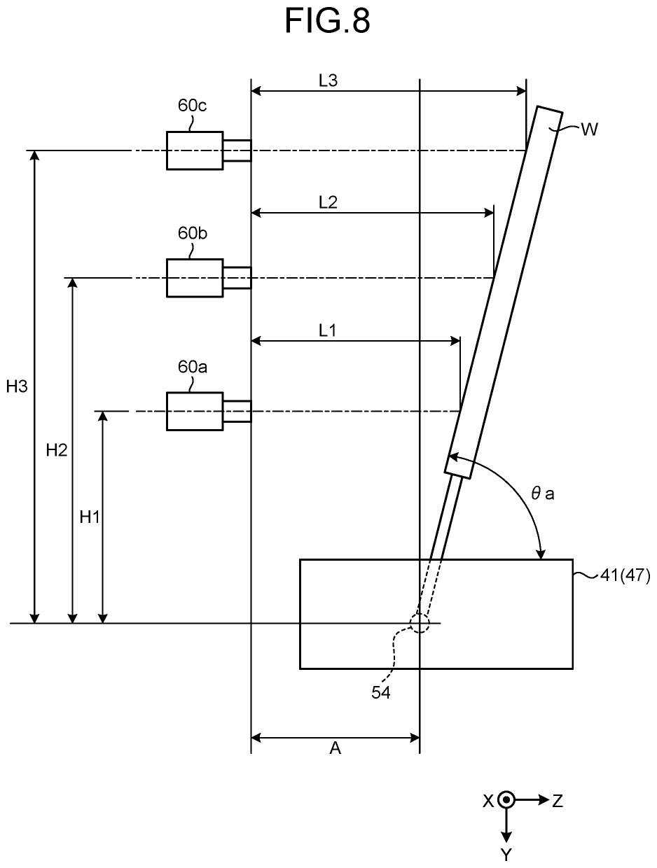

Next, a second adjustment device is described using FIG. 8. FIG. 8 is a diagram describing a method for adjusting the inclination in the height direction (the inclination with respect to the Y-axis) of the workpiece.

The surface treatment apparatus 10 includes laser length measuring machines 60a, 60b, and 60c in the interior of the load lock chamber 20a. The laser length measuring machines 60a, 60b, and 60c are installed at different height positions along the Y-axis. That is, the laser length measuring machines 60a, 60b, and 60c are installed at positions of heights H1, H2, and H3 from a reference position (for example, the position of the attachment shaft 54), respectively. The positions in the Z-axis direction of the laser length measuring machines 60a, 60b, and 60c are the same.

Upon emitting laser light of a predetermined wavelength, each of the laser length measuring machines 60a, 60b, and 60c measures a shift between the phase of the emitted laser light and the phase of the laser light reflected by the surface of the object and returned to the laser length measuring machines 60a, 60b, or 60c. Then, distances L1m, L2m, and L3m to the surface of the workpiece W housed in the load lock chamber 20a are measured on the basis of the measured phase shifts.

FIG. 8 illustrates a state where the workpiece W is mounted with an inclination with respect to the Y-axis in a distortion-free state. More specifically, the workpiece W is mounted with an inclination of an angle (90−θa) with respect to the Y-axis. In this case, the theoretical distances L1, L2, and L3 measured by the laser length measuring machines 60a, 60b, and 60c are calculated by Formulas (1), (2), and (3), respectively.

L1=(tan(90−θa)×H1)+A (1)

L2=(tan(90−θa)×H2)+A (2)

L3=(tan(90−θa)×H3)+A (3)

In Formulas (1) to (3), A is the distance from each of the laser length measuring machines 60a, 60b, and 60c to the attachment shaft 54 (see FIGS. 5 to 7), which is a rotation axis when rotating the workpiece W around axis θ.

On the other hand, when the workpiece W has distortion, the theoretical distances L1, L2, and L3 as in Formulas (1) to (3) are not measured. Thus, the surface treatment apparatus 10 has a function of changing the inclination with respect to the Y-axis of the workpiece W.

Specifically, the surface treatment apparatus 10 changes the inclination with respect to the Y-axis of the workpiece W (that is, the angle (90−θa)) so that the sum of the respective difference values between the distances L1m, L2m, and L3m actually measured by the laser length measuring machines 60a, 60b, and 60c and the theoretical distances L1, L2, and L3 is minimized.

Although FIG. 8 describes an example in which three laser length measuring machines 60a, 60b, and 60c are used, one laser length measuring machine 60a may be moved along the Y-axis to measure distance at different height positions. Further, the number of places where distance is measured is not limited to three, and distance may be measured at a larger number of height positions.

[1-6. Description of Method for Adjusting Orientation of Workpiece]

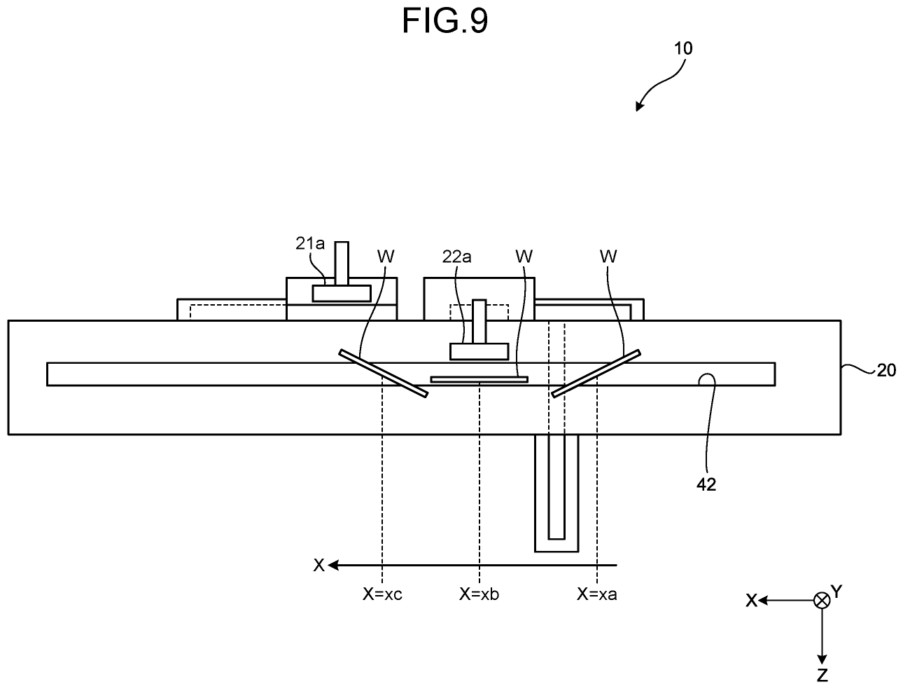

Next, a method for adjusting the orientation of a workpiece W is described using FIG. 9. FIG. 9 is a diagram describing how the orientation of a workpiece is adjusted when performing surface treatment.

While performing sputtering, the surface treatment apparatus 10 controls the rotation of the B-axis rotation motor 57 to swing the workpiece W around axis B. By this swinging, the orientation (normal direction) of the workpiece W is adjusted to an orientation corresponding to the position in the X-axis direction. More specifically, as illustrated in FIG. 9, the normal direction of the workpiece W is adjusted to face the sputtering electrode 22a.

For example, when the workpiece W conveyed along the groove 42 is at a position of X=xa, the B-axis rotation motor 57 adjusts the normal direction of the workpiece W so that the normal direction faces the sputtering electrode 22a.

When the workpiece W is at a position of X=xb, the B-axis rotation motor 57 adjusts the normal direction of the workpiece W so that the normal direction faces the sputtering electrode 22a.

When the workpiece W is at a position of X=xc, the B-axis rotation motor 57 adjusts the normal direction of the workpiece W so that the normal direction faces the sputtering electrode 22a.

The B-axis rotation motor 57 controls the rotation of the B-axis rotation motor 57 on the basis of the position in the X-axis direction of the workpiece W and the position of the sputtering electrode 22a.

Thus, the surface of the workpiece W can be still more uniformly and efficiently surface-treated by swinging the workpiece W around axis B to adjust the normal direction of the workpiece W so that the normal direction faces the sputtering electrode 22a.

After sputtering on the workpiece W is completed by the sputtering electrode 22a, the surface treatment apparatus 10 once moves the workpiece W in the negative direction of the X-axis (the right direction in FIG. 9). Next, plasma treatment by the HCD electrode 21a is performed. Also when performing plasma treatment, the B-axis rotation motor 57 adjusts the normal direction of the workpiece W so that the normal direction faces the sputtering electrode 22a.

Although not illustrated in FIG. 9, while performing sputtering and plasma treatment on the workpiece W, the surface treatment apparatus 10 controls the rotation of the C-axis rotation motor 55 to swing the workpiece W around axis C. By this swinging, the surface of the workpiece W is still more uniformly surface-treated.

The specific swing pattern around axis B and the specific swing pattern around axis C are appropriately determined according to the workpiece W to be used, the electrode to be used, the content of surface treatment, the conditions of surface treatment, etc.

[1-7. Description of Structure of HCD Electrode]

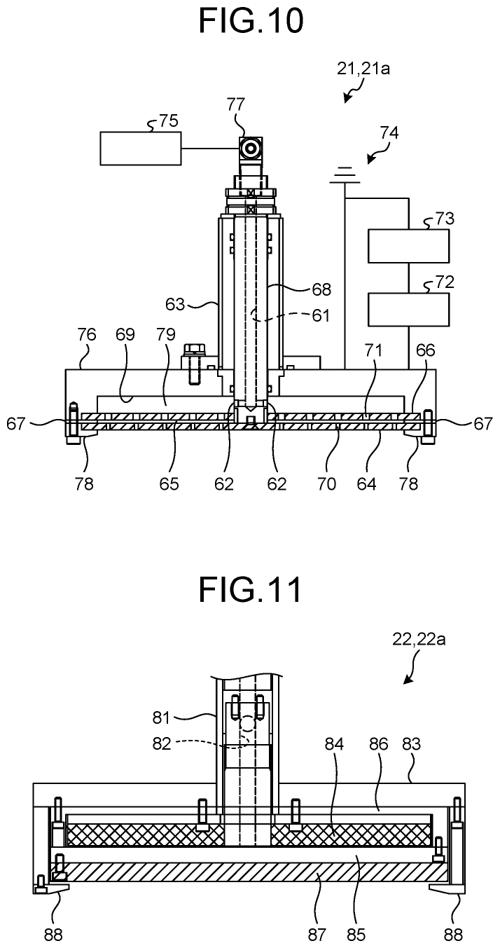

Next, a structure of the HCD electrode 21a is described using FIG. 10. FIG. 10 is a cross-sectional view illustrating an example of a structure of an HCD electrode.

The HCD electrode 21a included in the plasma generation apparatus 21 includes a gas supply pipe 68 for supplying a gas used to generate plasma, such as argon, and a pair of plate-shaped conductor units 64 and 66 for generating plasma from gas supplied from the gas supply pipe 68 by high-frequency voltage.

A gas flow path 61 running along the extending direction of the gas supply pipe 68 is formed in the interior of the gas supply pipe 68, and gas is supplied from the outside of the chamber 20 into the chamber 20 through the gas flow path 61. A gas supply unit 77 that supplies gas to the gas supply pipe 68 is connected to an end portion of the gas supply pipe 68 outside the chamber 20, and a gas supply hole 62 that is a hole for introducing gas flowing through the gas flow path 61 into the chamber is formed in an end portion of the gas supply pipe 68 inside the chamber 20. Gas is supplied to the gas supply unit 77 via a mass flow controller (MFC) 75 that includes a mass flowmeter provided with a flow rate control function.

The pair of plate-shaped conductor units 64 and 66 are each formed in a flat plate shape, and are formed by arranging metal plates such as aluminum or other conductor plates in parallel. The plate-shaped conductor units 64 and 66 are supported by a support plate 76. The support plate 76 is formed of, for example, an insulating material such as glass or ceramic. The support plate 76 is formed in a shape in which a protrusion is formed over the entire periphery near the outer periphery on one surface side of the plate. In other words, the support plate 76 is formed in a plate-like shape in which a recess 69 recessed along the outer periphery of the support plate 76 is formed on one surface side.

The surface of the support plate 76 on the side where the recess 69 is not formed is supported by a cylindrical support member 63 surrounding the gas supply pipe 68 along the extending direction. The gas supply pipe 68 passes through the inside of the cylindrical member of the support member 63, extends to the position of the support plate 76, and penetrates the support plate 76. The gas supply hole 62 formed in the gas supply pipe 68 is placed in a portion of the support plate 76 where the recess 69 is formed.

The pair of plate-shaped conductor units 64 and 66 are arranged on the side of the support plate 76 where the recess 69 is formed, covering the recess 69. At this time, a spacer 67 is placed near the outer periphery between the pair of plate-shaped conductor units 64 and 66, and the pair of plate-shaped conductor units are stacked via the spacer 67. In portions other than the spacer 67 of the pair of plate-shaped conductor units 64 and 66 stacked via the spacer 67, the plate-shaped conductor unit 64 and the plate-shaped conductor unit 66 are separated from each other to form a void portion 65. The spacing of the void portion 65 is preferably appropriately set according to the gas to be introduced or the frequency of power to be supplied in the plasma generation apparatus 21, the size of the electrode, etc., and is, for example, about 3 mm to 12 mm.

The pair of plate-shaped conductor units 64 and 66 are held by a holding member 78 that is a member for holding the plate-shaped conductor units 64 and 66 in a state where the plate-shaped conductor units 64 and 66 are stacked via the spacer 67. That is, the holding member 78 is placed on the opposite side of the plate-shaped conductor units 64 and 66 from the side where the support plate 76 is located, and is attached to the support plate 76 in a state where the plate-shaped conductor units 64 and 66 are sandwiched between the holding member 78 and the support plate 76.

The pair of plate-shaped conductor units 64 and 66 are arranged to cover the recess 69 in the support plate 76 in this manner, and a space is formed between the recess 69 of the support plate 76 and the plate-shaped conductor units 64 and 66 in a state where the plate-shaped conductor units 64 and 66 are held by the holding member 78.

In the case where, out of the pair of plate-shaped conductor units 64 and 66 arranged in a stacked manner, the plate-shaped conductor unit 66 is placed on the support plate 76 side and the plate-shaped conductor unit 64 is placed on the holding member 78 side, this space is defined by the recess 69 of the support plate 76 and the plate-shaped conductor unit 66. The space thus formed is formed as a gas introduction portion 79 into which gas supplied by the gas supply pipe 68 is introduced. The gas supply hole 62 of the gas supply pipe 68 is located at the gas introduction portion 79, and is opened toward the gas introduction portion 79. The gas introduction portion 79 is defined by closely attaching the support plate 76 and the plate-shaped conductor unit 66 together.

Large numbers of through holes 70 and 71 penetrating in the thickness direction are formed in the pair of plate-shaped conductor units 64 and 66, respectively. That is, in the plate-shaped conductor unit 66 located on the inflow side of gas supplied by the gas supply pipe 68, a plurality of through holes 71 are formed at predetermined intervals in a matrix form when viewed in the thickness direction of the plate-shaped conductor unit 66, and in the plate-shaped conductor unit 64 located on the outflow side of gas supplied by the gas supply pipe 68, a plurality of through holes 70 are formed at predetermined intervals in a matrix form when viewed in the thickness direction of the plate-shaped conductor unit 64.

The through hole 70 of the plate-shaped conductor unit 64 and the through hole 71 of the plate-shaped conductor unit 66 are cylindrical holes, and both the through holes 70 and 71 are coaxially arranged. That is, the through hole 70 of the plate-shaped conductor unit 64 and the through hole 71 of the plate-shaped conductor unit 66 are arranged in positions where the centers of the through holes are aligned. Of these through holes, the through hole 70 of the plate-shaped conductor unit 64 is smaller in diameter than the through hole 71 of the plate-shaped conductor unit 66 on the gas inflow side. Thus, pluralities of through holes 70 and 71 are formed in the pair of plate-shaped conductor units 64 and 66 to form a hollow electrode structure, and generated plasma gas flows at high density through the pluralities of through holes 70 and 71.

The void portion 65 is interposed between the parallel flat plate-shaped conductor units 64 and 66, and the void portion 65 functions as a capacitor having capacitance. A conductive portion (illustration omitted) is formed in each of the support plate 76 and the plate-shaped conductor units 64 and 66 by a conductive member, and the support plate 76 is connected to the ground 74 and also the plate-shaped conductor unit 66 is connected to the ground 74 by the conductive portions. One end portion of a high-frequency power source (RF) 73 is connected to the ground 74, and another end portion of the high-frequency power source 73 is electrically connected to the plate-shaped conductor unit 64 via a matching box (MB) 72 for adjusting capacitance or the like to obtain matching with plasma. Therefore, when the high-frequency power source 73 is operated, the potential of the plate-shaped conductor unit 64 oscillates plus and minus at a predetermined frequency, for example 13.56 MHz, etc.

Then, surface treatment such as film formation or cleaning of the workpiece W in the chamber 20 is performed by plasma gas flowing out from the through holes 70.

[1-8. Description of Structure of Sputtering Electrode]

Next, a structure of the sputtering electrode 22a is described using FIG. 11. FIG. 11 is a cross-sectional view illustrating an example of a structure of a sputtering electrode.

The sputtering apparatus 22 includes a cooling water pipe 81 through which cooling water flows, a magnet 84 that generates a magnetic field, a target 87 that ejects atoms used for film formation by a process in which, in the interior of a magnetic field generated by the magnet 84, an inert gas (for example, argon) supplied from a not-illustrated gas supply apparatus and passed in from a not-illustrated gas inflow portion is ionized and collided against the target 87, a cooling jacket 85 that cools the target 87, and a support plate 83 that supports the magnet 84, the target 87, and the cooling jacket 85. The cooling water pipe 81 penetrates the support plate 83. The target 87 is, for example, an aluminum plate, and aluminum atoms ejected from the target 87 adhere to the surface of the workpiece W to form an aluminum thin film on the surface of the workpiece W.

A cooling water path 82 running along the extending direction of the cooling water pipe 81 is formed in the interior of the cooling water pipe 81. Although not illustrated in FIG. 11, the cooling water path 82 includes a water path for supplying cooling water for cooling from the outside of the chamber 20 to the cooling jacket 85 and a water path for discharging cooling water that has been used for cooling from the cooling jacket 85 to the outside of the chamber 20. In this manner, the cooling water pipe 81 circulates cooling water between the outside of the chamber 20 and the cooling jacket 85 placed in the chamber 20. An inflow path and a discharge path of cooling water, which are not illustrated in FIG. 11, are connected to an end portion of the cooling water pipe 81 outside the chamber 20. On the other hand, an end portion of the cooling water pipe 81 on the other end side (inside the chamber 20) is connected to the cooling jacket 85. A cooling water flow path is formed in the interior of the cooling jacket 85, and cooling water flows. Thereby, cooling water circulates between the outside of the chamber and the cooling jacket 85. The cooling water is supplied from a not-illustrated cooling apparatus.

The support plate 83 supports the magnet 84, the cooling jacket 85, and the target 87 in a stacked state. Specifically, the support plate 83, the magnet 84, the cooling jacket 85, and the target 87 are each formed in a plate-like shape, and the support plate 83 is formed in a larger shape in a planar view than the magnet 84, the cooling jacket 85, and the target 87. Thus, the vicinity of the outer periphery of the surface of the target 87 on the opposite side to the surface on the cooling jacket 85 side is supported by a holding member 88 in a state where the magnet 84, the cooling jacket 85, and the target 87 are stacked in this order from the support plate 83 side, and thereby the magnet 84, the cooling jacket 85, and the target 87 are held by the support plate 83 and the holding member 88. The magnet 84, the cooling jacket 85, and the target 87 held by the holding member 88 are held in a state where also their outer periphery portions are surrounded by the holding member 88.

At this time, an insulating material 86 is placed between the support plate 83 and the magnet 84, and the insulating material 86 is placed also on an outer periphery portion in a planar view of the magnet 84. That is, the insulating material 86 is placed between the support plate 83 and the magnet 84 and between the magnet 84 and the holding member 88. Therefore, the magnet 84 is held by the support plate 83 and the holding member 88 via the insulating material 86.

The sputtering apparatus 22 performs what is called sputtering, which forms a thin film on the surface of the workpiece W. When the sputtering apparatus 22 performs sputtering, the interior of the chamber 20 is depressurized by a not-illustrated exhaust apparatus, and then gas used for sputtering is passed from a not-illustrated gas supply apparatus into the interior of the chamber 20. Then, the gas in the chamber 20 is ionized by a magnetic field generated by the magnet 84 of the sputtering apparatus 22, and the ions are collided against the target 87. Thereby, atoms of the target 87 are ejected from the surface of the target 87.

For example, in the case where aluminum is used for the target 87, when ions of gas ionized in the vicinity of the target 87 collide with the target 87, the target 87 ejects aluminum atoms. The aluminum atoms ejected from the target 87 move in the positive direction of the Z-axis. Since the workpiece W is located in a position facing the surface of the target 87 in the chamber 20, the aluminum atoms ejected from the target 87 move toward the workpiece W and adhere to the workpiece W, and are deposited on the surface of the workpiece W. Thereby, a thin film corresponding to the substance forming the target 87 is formed on the surface of the workpiece W.

[1-9. Description of Specific Surface Treatment]

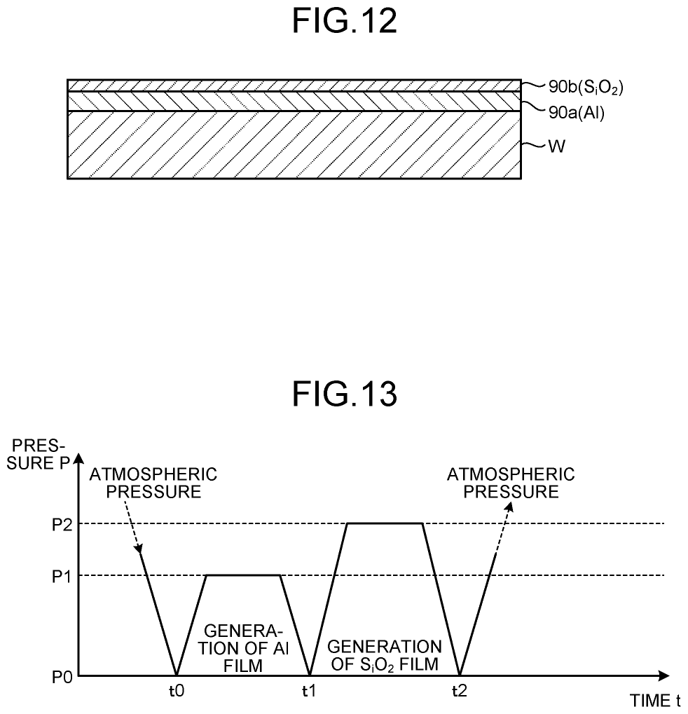

Next, a specific example of surface treatment performed by the surface treatment apparatus 10 is described using FIGS. 12 and 13. FIG. 12 is a diagram illustrating an example of surface treatment performed on a workpiece by the surface treatment apparatus. FIG. 13 is a diagram illustrating an example of pressure change in a chamber when the surface treatment apparatus performs surface treatment on a workpiece.

In the present embodiment, the surface treatment apparatus 10 generates, for example, an Al layer 90a and a SiO₂ layer 90b on one surface of the workpiece W.

First, the surface treatment apparatus 10 operates the sputtering apparatus 22 to generate an Al layer 90a that is a thin film of aluminum (Al) on the surface of the workpiece W. At this time, as illustrated in FIG. 13, the interior of the chamber 20 is brought from a state where the pressure is reduced to pressure P0 (for example, 10⁻² to 10⁻³ Pa) at time t0 into a state where the pressure is increased to pressure P1 by passing gas in, and the interior of the chamber 20 performs sputtering of aluminum in this pressurized state. In this case, aluminum is used for the target 87. Pressure P1 is, for example, 20 Pa. After the sputtering is completed, the interior of the chamber 20 is decompressed again to pressure P0 at time t1. In FIG. 13, the vertical axis represents the pressure P, and a lower side indicates a more decompressed state.

While the sputtering is being performed, the surface treatment apparatus 10 swings the workpiece W around axis B and around axis C. Thereby, a uniform Al layer 90a is generated on the surface of the workpiece W.

Next, the surface treatment apparatus 10 operates the plasma generation apparatus 21 to generate a SiO₂ layer 90b on the surface of the Al layer 90a of the workpiece W. At this time, the surface treatment apparatus 10 brings the interior of the chamber 20 from a state where the pressure is reduced to pressure P0 at time t1 into a state where the pressure is increased to pressure P2 by passing gas in.

Then, the plasma generation apparatus 21 generates a SiO₂ layer 90b (a polymerized film) on the surface of the Al layer 90a of the workpiece W. Pressure P2 is set to a pressure higher than pressure P1. Pressure P2 is, for example, 30 Pa. After the SiO₂ layer 90b is generated, the interior of the chamber 20 is decompressed again to pressure P0 at time t2.

While the plasma treatment is being performed, the surface treatment apparatus 10 swings the workpiece W around axis B and around axis C. Thereby, a uniform SiO₂ layer 90b is generated on the surface of the workpiece W.

After the plasma treatment is ended, the surface treatment apparatus 10 moves the workpiece W to the load lock chamber 20a. Then, the surface treatment apparatus 10 closes the shutter 30, and increases the pressure of the interior of the load lock chamber 20a to atmospheric pressure. After that, the workpiece W for which film formation treatment is completed is taken out from the chamber 20.

[1-10. Description of Flow of Processing Performed by Surface Treatment Apparatus]

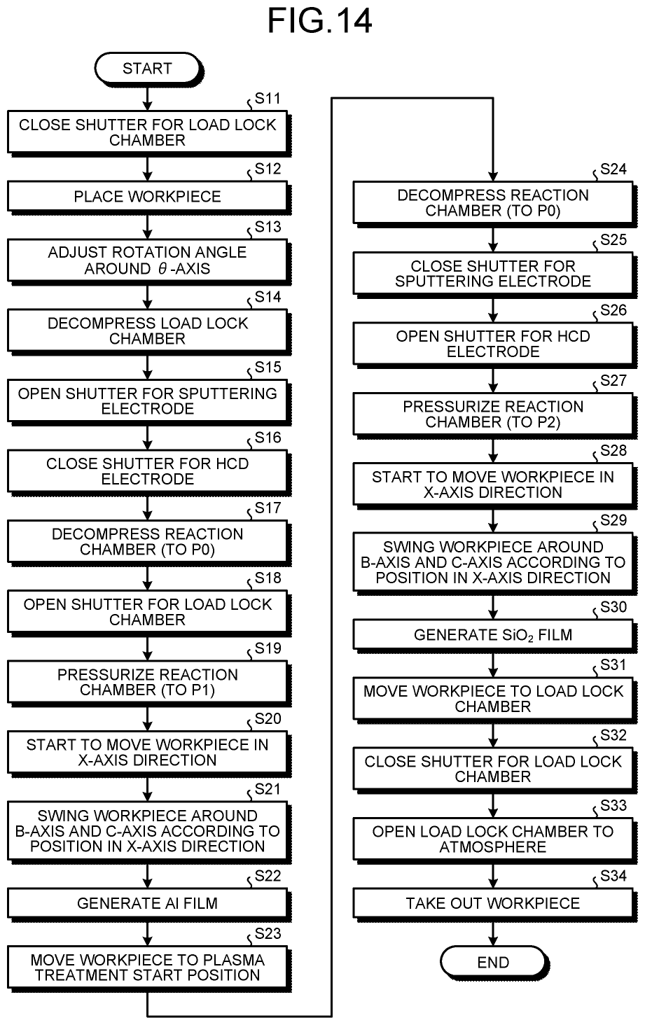

Next, a flow of processing performed by the surface treatment apparatus 10 is described using FIG. 14. FIG. 14 is a flowchart illustrating an example of a flow of processing performed when the surface treatment apparatus performs surface treatment on a workpiece.

The surface treatment apparatus 10 closes the shutter 30 of the load lock chamber 20a (Step S11).

The operator of the surface treatment apparatus places a workpiece W in the load lock chamber 20a (Step S12).

The surface treatment apparatus 10 measures distances L1m, L2m, and L3m to the surface of the workpiece W with the laser length measuring machines 60a, 60b, and 60c, respectively. Then, the rotation angle around the θ-axis of the workpiece W is adjusted so that the errors between the measured distances L1m, L2m, and L3m and the theoretical distances L1, L2, and L3 are minimized (Step S13).

The surface treatment apparatus 10 decompresses the interior of the load lock chamber 20a (Step S14).

The surface treatment apparatus 10 opens the shutter 32 for the sputtering electrode 22a (Step S15).

The surface treatment apparatus 10 closes the shutter 31 for the BCD electrode 21a (Step S16).

The surface treatment apparatus 10 decompresses the interior of the reaction chamber 20b of the chamber 20 to pressure P0 (Step S17).

The surface treatment apparatus 10 opens the shutter 30 of the load lock chamber 20a (Step S18).

The surface treatment apparatus 10 pressurizes the interior of the reaction chamber 20b of the chamber 20 to pressure P1 (Step S19).

The surface treatment apparatus 10 starts movement in the X-axis direction of the workpiece W (Step S20).

The surface treatment apparatus 10 swings the workpiece W around the B-axis and the C-axis according to the position in the X-axis direction (Step S21).

The sputtering apparatus 22 generates an Al film on the surface of the workpiece W (Step S22).

The surface treatment apparatus 10 moves the workpiece W to the start position of plasma treatment (Step S23).

The surface treatment apparatus 10 decompresses the interior of the reaction chamber 20b of the chamber 20 to pressure P0 (Step S24).

The surface treatment apparatus 10 closes the shutter 32 for the sputtering electrode 22a (Step S25).

The surface treatment apparatus 10 opens the shutter 31 for the HCD electrode 21a (Step S26).

The surface treatment apparatus 10 pressurizes the interior of the reaction chamber 20b of the chamber 20 to pressure P2 (Step S27).

The surface treatment apparatus 10 starts movement in the X-axis direction of the workpiece W (Step S28).

The surface treatment apparatus 10 swings the workpiece W around the B-axis and the C-axis according to the position in the X-axis direction (Step S29).

The plasma generation apparatus 21 generates a SiO₂ film on the surface of the workpiece W (Step S30).

The surface treatment apparatus 10 moves the workpiece W to the load lock chamber 20a (Step S31).

The surface treatment apparatus 10 closes the shutter 30 of the load lock chamber 20a (Step S32).

The surface treatment apparatus 10 opens the load lock chamber 20a to the atmosphere (Step S33).

The operator of the surface treatment apparatus takes out the workpiece W for which surface treatment is completed from the load lock chamber 20a (Step S34).

The series of processing described above may be executed on the basis of an instruction by the operator, or may be automatically executed in accordance with a sequence created in advance.

[1-11. Operation and Effect of First Embodiment]

As described above, the surface treatment apparatus 10 of the first embodiment includes: a workpiece mounting unit 50 (a mounting device) on which a workpiece W is mounted; a chamber 20 (a housing unit) that houses the workpiece W mounted on the workpiece mounting unit 50; a plasma generation apparatus 21 and a sputtering apparatus 22 (a surface treatment device) each of which performs at least one kind of surface treatment on the workpiece W housed in the chamber 20; a workpiece conveyance unit 40 (a conveyance device) that conveys the workpiece W mounted on the workpiece mounting unit 50 along the plasma generation apparatus 21 and the sputtering apparatus 22; and a C-axis rotation motor 55 and a B-axis rotation motor 57 (a first adjustment device) that adjust the orientation of the workpiece W according to the conveyance position by the workpiece conveyance unit 40 and the position of the plasma generation apparatus 21 or the sputtering apparatus 22. Therefore, a surface treatment apparatus suitable for performing surface treatment of a small amount to a medium amount of workpieces W can be provided. Further, the surface treatment apparatus 10 performs film formation while moving the workpiece W; thus, the width of the electrode can be narrowed, and the output per unit area of the electrode can be increased accordingly. Therefore, film formation treatment can be performed even in a low vacuum, and thus the vacuuming time can be shortened. Further, because of a low vacuum, the amount of outgassing generated in the chamber 20 during film formation treatment is reduced; thus, the vacuuming time and the exhaust time are reduced, and the production cycle time can be shortened. In the case where the output per unit area of the electrode is set equal to that of a conventional electrode, the power output of the electrode can be reduced, and the cost performance of the apparatus can be improved.

Further, in the surface treatment apparatus 10 of the first embodiment, the B-axis rotation motor 57 (a first adjustment device) adjusts the orientation of the workpiece W around axis B orthogonal to the conveyance direction of the workpiece conveyance unit 40 (a conveyance device), the normal direction of the HCD electrode 21a (an electrode) included in the plasma generation apparatus 21, and the normal direction of the sputtering electrode 22a (an electrode) included in the sputtering apparatus 22 (a surface treatment device). Therefore, the surface of the workpiece W can be uniformly and efficiently surface-treated.

Further, in the surface treatment apparatus 10 of the first embodiment, the C-axis rotation motor 55 (a first adjustment device) adjusts the orientation of the workpiece W around the normal direction of the workpiece W. Therefore, the surface of the workpiece W can be uniformly surface-treated.

The surface treatment apparatus 10 of the first embodiment further includes laser length measuring machines 60a, 60b, and 60c (a measurement device) that measure the distortion in the height direction of the workpiece W before the plasma generation apparatus 21 or the sputtering apparatus 22 (a surface treatment device) performs surface treatment, and a θ-axis rotation motor 53 (a second adjustment device) that adjusts the inclination in the height direction of the workpiece W to a predetermined value on the basis of the distortion of the workpiece W measured by the laser length measuring machines 60a, 60b, and 60c. Therefore, the state of distortion of the workpiece W to be surface-treated can be accurately measured.

Further, in the surface treatment apparatus 10 of the first embodiment, the laser length measuring machines 60a, 60b, and 60c (a measurement device) measure the distortion in the height direction of the workpiece W on the basis of the distances L1m, L2m, and L3m between the laser length measuring machines 60a, 60b, and 60c and the workpiece W measured at a plurality of different positions in the height direction of the workpiece W. Therefore, the attitude of the workpiece W can be adjusted so that the influence of distortion when surface treatment is performed is minimized.

Further, in the surface treatment apparatus 10 of the first embodiment, the workpiece mounting unit 50 (a mounting device) includes a moving stage 41 (a pedestal member) conveyed by the workpiece conveyance unit 40 (a conveyance device), an attachment stage 47 (a base member) that is installed on the moving stage 41 and fixes the workpiece W, and an attachment shaft 48 (a support member) that supports the workpiece W on the attachment stage 47. Therefore, the orientation of the workpiece W can be adjusted by adjusting the orientation of the attachment stage 47 with respect to the moving stage 41 and the rotation angle of the attachment shaft 48 with respect to the attachment stage 47.

Further, in the surface treatment apparatus 10 of the first embodiment, the width of each of the electrodes included in the plasma generation apparatus 21 and the sputtering apparatus 22 (a surface treatment device) along the conveyance direction of the workpiece conveyance unit (a conveyance device) is smaller than the width of the workpiece W along the conveyance direction of the workpiece conveyance unit 40. Therefore, the overall size of the surface treatment apparatus 10 can be reduced.

Further, the surface treatment apparatus 10 of the first embodiment includes a plasma generation apparatus 21 (a surface treatment device) that performs surface treatment of the workpiece W by irradiating the workpiece W with plasma. Therefore, for example, by generating a SiO₂ layer on the surface of the workpiece W, the adhesion of a thin film formed thereafter can be improved.

Further, the surface treatment apparatus 10 of the first embodiment includes a sputtering apparatus 22 (a surface treatment device) that performs sputtering on the workpiece W. Therefore, a desired thin film can be formed on the surface of the workpiece W.

The surface treatment apparatus 10 of the first embodiment further includes shutters 31 and 32 (shielding members) each of which, when one of the plasma generation apparatus 21 and the sputtering apparatus 22 (surface treatment device) performs surface treatment on the workpiece W, blocks a surface treatment device other than the above surface treatment device. Therefore, contamination of an electrode included in a surface treatment device not involved in the surface treatment can be prevented.

[1-12. Modification Example of First Embodiment]

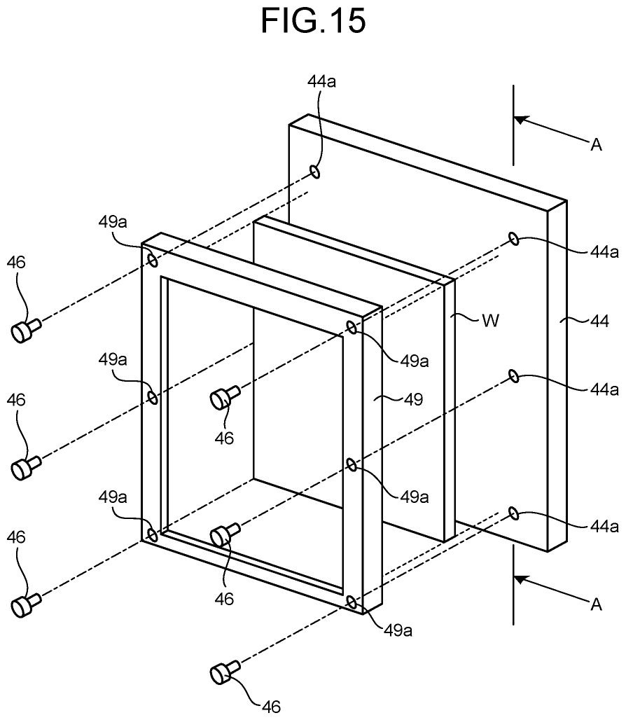

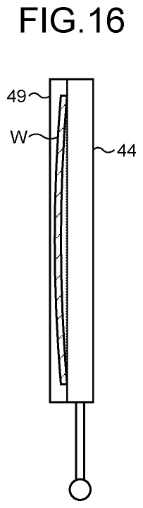

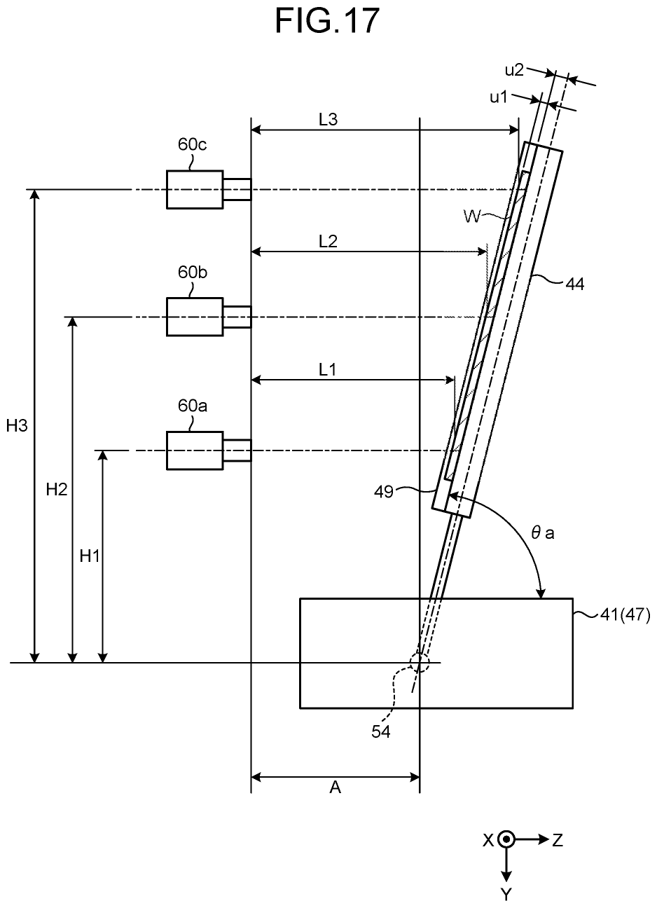

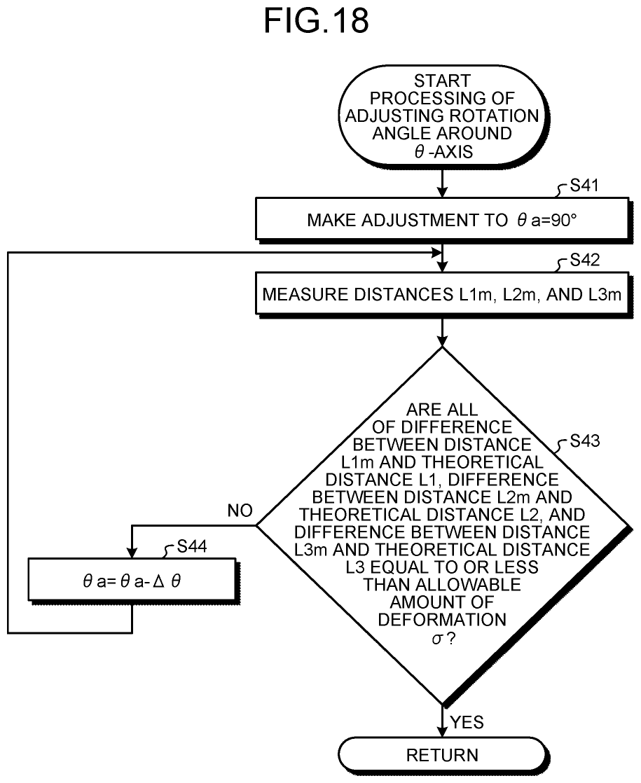

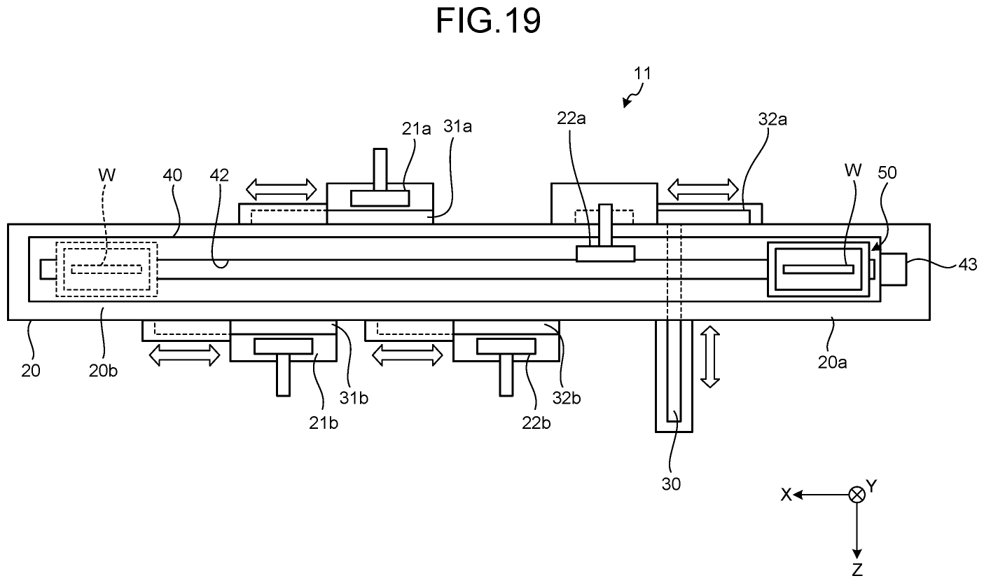

Next, a modification example of the first embodiment is described using FIGS. 15 to 18. FIG. 15 is an exploded perspective view illustrating a workpiece attachment structure. FIG. 16 is a cross-sectional view illustrating an example of a state where a workpiece is sandwiched between a bedplate and a base material holder. FIG. 17 is a diagram describing in more detail a method for adjusting the inclination in the height direction of a workpiece. FIG. 18 is a flowchart illustrating an example of a flow of processing of adjusting the inclination in the height direction of a workpiece.

Herein, a case where surface treatment is performed on the entire surface of a workpiece W is described. That is, as illustrated in FIG. 15, a workpiece W is held in a state of being sandwiched between a bedplate 44 and a base material holder 49. Unlike the base material holder 45 described above, the base material holder 49 does not have a grid-like pressing member. Therefore, surface treatment can be performed over the entire surface of the workpiece W. The bedplate 44 and the base material holder 49 are screwed with screws 46. More specifically, screws 46 inserted into a plurality of attachment holes 49a formed in an outer edge portion of the base material holder 49 are coupled with female screws 44a formed in the bedplate 44, and thereby the bedplate 44 and the base material holder 49 are coupled in a state of sandwiching the workpiece W.

At this time, the workpiece W is grasped only by the outer frame of the base material holder 49, and therefore warpage may occur due to the weight of the workpiece W, as illustrated in FIG. 16. If surface treatment is performed in the state where the workpiece W is warped, residual stress may be generated in the formed film itself. The residual stress may cause defects such as cracks or peeling in the workpiece W.

To reduce such warpage of the workpiece W, as illustrated in FIG. 17, it is desirable to hold the bedplate 44 in a state of being inclined on the bedplate 44 side by angle θa instead of being perpendicular to the moving stage 41. Thus, by inclining the bedplate 44 by angle θa, the surface of the workpiece W is kept in a state close to a straight line and set to have small warpage.

Next, a method for adjusting the inclination in the height direction (the inclination with respect to the Y-axis) of the workpiece W is described in more detail using FIG. 17. FIG. 17 is a more detailed diagram in which the thickness u1 of the workpiece W and a value u2 of ½ of the thickness of the bedplate 44 are added to FIG. 8 described above.

FIG. 17 illustrates a state where the workpiece W is mounted with an inclination with respect to the Y-axis in a distortion-free state. More specifically, the workpiece W is mounted with an inclination of an angle (90−θa) with respect to the Y-axis. In this case, the theoretical distances L1, L2, and L3 measured by the laser length measuring machines 60a, 60b, and 60c are calculated by Formulas (4), (5), and (6), respectively. Formulas (4), (5), and (6) are formulas detailed by adding the thickness u1 of the workpiece W and the value u2 of ½ of the thickness of the bedplate 44 to Formulas (1), (2), and (3) described above, respectively.

L1=(tan(90−θa)×H1)+A−(u1+u2)/cos(90−θa) (4)

L2=(tan(90−θa)×H2)+A−(u1+u2)/cos(90−θa) (5)

L3=(tan(90−θa)×H3)+A−(u1+u2)/cos(90−θa) (6)

When the workpiece W is warped as illustrated in FIG. 16, theoretical distances L1, L2, and L3 as in Formulas (4) to (6) are not measured. Thus, the surface treatment apparatus 10 adjusts the inclination with respect to the Y-axis of the workpiece W (that is, the angle (90−θa)) so that the warpage of the workpiece W is smaller than a predetermined value. Specifically, the surface treatment apparatus 10 adjusts the inclination with respect to the Y-axis, that is, the rotation angle around the θ-axis of the workpiece W so that all the respective difference values between the distances L1m, L2m, and L3m actually measured by the laser length measuring machines 60a, 60b, and 60c and the theoretical distances L1, L2, and L3 are equal to or less than an allowable amount of deformation 6. The allowable amount of deformation σ is obtained in advance by analysis or experiment. Since a portion where the workpiece W is greatly warped can be estimated in advance, only the distance of the estimated portion may be measured with a laser length measuring machine.

Next, a flow of processing of adjusting the rotation angle around the θ-axis performed by the surface treatment apparatus 10 is described using FIG. 18.

First, the surface treatment apparatus 10 adjusts the angle θa to 90° (Step S41). It is assumed that the original positions of the three laser length measuring machines 60a, 60b, and 60c are reset in advance by installing a level on the bedplate 44 to make adjustment to a state of θa=0.

Subsequently, the surface treatment apparatus 10 measures distance L1m, distance L2m, and distance L3m (Step S42).

Next, the surface treatment apparatus 10 determines whether or not all of the difference between the distance L1m and the theoretical distance L1 according to Formula (4), the difference between the distance L2m and the theoretical distance L2 according to Formula (5), and the difference between the distance L3m and the theoretical distance L3 according to Formula (6) are equal to or less than the allowable amount of deformation σ (Step S43). When it is determined that all the difference values are equal to or less than the allowable amount of deformation σ (Step S43: Yes), the surface treatment apparatus 10 ends the processing of adjusting the rotation angle around the θ-axis. On the other hand, when it is not determined that all the difference values are equal to or less than the allowable amount of deformation σ (Step S43: No), the procedure proceeds to Step S44.

When it is not determined in Step S43 that all the difference values are equal to or less than the allowable amount of deformation σ, the surface treatment apparatus 10 reduces the angle θa by a predetermined angle Δθ set in advance (Step S44). After that, the procedure returns to Step S42, and the processing described above is repeated.

### 2. Second Embodiment

Next, a surface treatment apparatus 11 of a second embodiment of the present disclosure is described. The surface treatment apparatus 11 performs surface treatment on both surfaces of a workpiece W.

[2-1. Operation and Effect of First Embodiment]

First, an internal structure of the surface treatment apparatus 11 is described using FIG. 19. FIG. 19 is a top view of the interior of a chamber of a surface treatment apparatus of the second embodiment.

The surface treatment apparatus 11 performs surface treatment on both surfaces of a workpiece W while conveying the workpiece W in the X-axis direction. The basic structure of the surface treatment apparatus 11 is the same as the structure of the surface treatment apparatus 10 (see FIG. 2). However, in order to perform surface treatment on both surfaces of the workpiece W, electrodes that perform surface treatment are provided on both sides in the Z-axis direction across a workpiece conveyance unit 40. In the example of FIG. 2, an HCD electrode 21a and a sputtering electrode 22a are provided on the negative side of the Z-axis. In addition, an HCD electrode 21b and a sputtering electrode 22b are provided on the positive side of the Z-axis.

The HCD electrode 21a and the sputtering electrode 22a include a shutter 31a and a shutter 32a that close or open the electrodes, respectively. The shutter 31a and the shutter 32a correspond to the shutter 31 and the shutter 32 described in the first embodiment, respectively. The shutters 31a and 32a are each an example of a shielding member in the present disclosure.

The HCD electrode 21b and the sputtering electrode 22b include a shutter 31b and a shutter 32b that close or open the electrodes, respectively. The shutter 31b moves in the positive direction of the X-axis to expose the HCD electrode 21b when performing plasma treatment on the surface of the workpiece W on the positive side of the Z-axis. Further, the shutter 31b moves in the negative direction of the X-axis to house the HCD electrode 21b. Thereby, contamination of an electrode that is not used is prevented. The shutter 31b is an example of a shielding member in the present disclosure.

The shutter 32b moves in the negative direction of the X-axis to expose the sputtering electrode 22b when performing sputtering treatment on the surface of the workpiece W on the positive side of the Z-axis. Further, the shutter 32b moves in the positive direction of the X-axis to house the sputtering electrode 22a. Thereby, contamination of an electrode that is not used is prevented. The shutter 32b is an example of a shielding member in the present disclosure.

When performing surface treatment with the sputtering electrode 22a and the HCD electrode 21a and when performing surface treatment with the sputtering electrode 22b and the HCD electrode 21b, the surface treatment apparatus 11 swings the workpiece W around axis B and axis C in the same swing pattern.

Further, when performing surface treatment with the sputtering electrode 22a and the HCD electrode 21a and when performing surface treatment with the sputtering electrode 22b and the HCD electrode 21b, the surface treatment apparatus 11 changes the rotation angle in the axis θ direction of the workpiece W to keep fixed the attitude of the workpiece W with respect to the respective electrode surfaces.

[2-2. Description of Workpiece Attachment Structure]

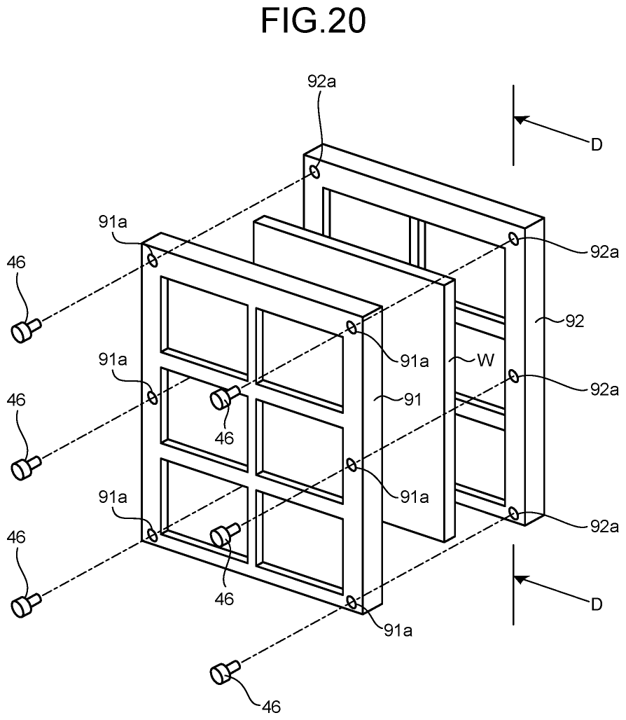

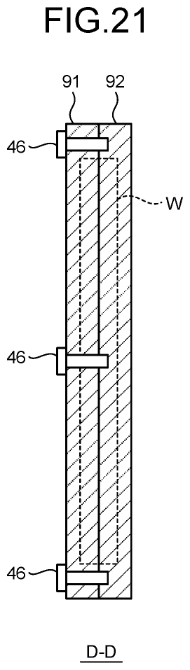

Next, a workpiece W attachment structure is described using FIGS. 20 and 21. FIG. 20 is an exploded perspective view illustrating a workpiece attachment structure in the surface treatment apparatus of the second embodiment. FIG. 21 is a cross-sectional view illustrating a workpiece attachment structure in the surface treatment apparatus of the second embodiment.

As illustrated in FIG. 20, a workpiece W is attached to a workpiece mounting unit 50 in a state of being sandwiched between two base material holders 91 and 92.

The base material holders 91 and 92 are each a plate-shaped member formed in a grid shape. As illustrated in FIG. 21, in each of the base material holders 91 and 92, the side to be in contact with the workpiece W is formed thin in accordance with the shape of the workpiece W. Therefore, when the workpiece W is sandwiched between the base material holders 91 and 92, the workpiece W is reliably sandwiched between the two base material holders 91 and 92.

A plurality of attachment holes 91a through which screws 46 penetrate are formed in an outer edge portion of the base material holder 91. The screw 46 inserted into the attachment hole 91a is coupled with a female screw 92a formed in the base material holder 92 to fix the base material holder 91 and the base material holder 92 in a state of sandwiching the workpiece W. The base material holder 91 and the base material holder 92 may be fixed using a one-touch clip or the like instead of the screw 46. Further, two workpieces W may be placed in a back-to-back stacked manner, and thereby the productivity of one-surface surface treatment can be improved.

[2-3. Operation and Effect of Second Embodiment]

As described above, in the surface treatment apparatus 11 of the second embodiment, the HCD electrode 21a and the sputtering electrode 22a, and the HCD electrode 21b and the sputtering electrode 22b included in a surface treatment device are installed to face both surfaces of the workpiece W. Therefore, surface treatment can be performed on both surfaces of the workpiece W.

Hereinabove, embodiments of the present invention are described; however, the embodiments described above are presented as examples, and do not intend to limit the scope of the present invention. This novel embodiment can be implemented in various other forms. In addition, various omissions, substitutions, and changes can be made without departing from the gist of the invention. In addition, this embodiment is included in the scope and gist of the invention, and is included in the invention described in the claims and the equivalent scope thereof.

### EXPLANATIONS OF LETTERS OR NUMERALS

10, 11 SURFACE TREATMENT APPARATUS
20 CHAMBER (HOUSING UNIT)
20a LOAD LOCK CHAMBER
20b REACTION CHAMBER
21 PLASMA GENERATION APPARATUS (SURFACE TREATMENT DEVICE)
21a HCD ELECTRODE (ELECTRODE)
22 SPUTTERING APPARATUS (SURFACE TREATMENT DEVICE)
22a SPUTTERING ELECTRODE (ELECTRODE) SHUTTER
31, 31a, 31b, 32, 32a, 32b SHUTTER (SHIELDING MEMBER)
40 WORKPIECE CONVEYANCE UNIT (CONVEYANCE DEVICE)
41 MOVING STAGE (PEDESTAL MEMBER)
42 GROOVE
43 CONVEYANCE MOTOR
44 BEDPLATE
45, 49, 91, 92 BASE MATERIAL HOLDER
46 SCREW
47 ATTACHMENT STAGE (BASE MEMBER)
48 ATTACHMENT SHAFT (SUPPORT MEMBER)
50 WORKPIECE MOUNTING UNIT (MOUNTING DEVICE)
51 C-AXIS ROTATION STAGE
52 θ-AXIS ROTATION STAGE
53 θ-AXIS ROTATION MOTOR (SECOND ADJUSTMENT DEVICE)
54, 56, 58 ATTACHMENT SHAFT
55 C-AXIS ROTATION MOTOR (FIRST ADJUSTMENT DEVICE)
57 B-AXIS ROTATION MOTOR (FIRST ADJUSTMENT DEVICE)
60a, 60b, 60c LASER LENGTH MEASURING MACHINE (MEASUREMENT DEVICE)
61 GAS FLOW PATH
62 GAS SUPPLY HOLE
63 SUPPORT MEMBER
64, 66 PLATE-SHAPED CONDUCTOR UNIT
65 VOID PORTION
67 SPACER
68 GAS SUPPLY PIPE
69 RECESS
70, 71 THROUGH HOLE
72 MATCHING BOX (MB)
73 HIGH-FREQUENCY POWER SOURCE (RF)
74 GROUND
75 MASS FLOW CONTROLLER (MFC)
76 SUPPORT PLATE
77 GAS SUPPLY UNIT
78 HOLDING MEMBER
79 GAS INTRODUCTION UNIT
81 COOLING WATER PIPE
82 COOLING WATER PATH
83 SUPPORT PLATE
84 MAGNET
85 COOLING JACKET
86 INSULATING MATERIAL
87 TARGET
88 HOLDING MEMBER
90a Al LAYER
90b SiO₂ LAYER
B, C, θ AXIS
H1, H2, H3 HEIGHT
L1, L2, L3 THEORETICAL DISTANCE
L1m, L2m, L3m DISTANCE
P0, P1, P2 PRESSURE
W WORKPIECE
θa ANGLE

1. A surface treatment apparatus comprising:
a mounting device on which a workpiece is mounted;
a housing unit that houses the workpiece mounted on the mounting device;
a surface treatment device that performs at least one kind of surface treatment on the workpiece housed in the housing unit;
a conveyance device that conveys the workpiece mounted on the mounting device along the surface treatment device; and
a first adjustment device that adjusts an orientation of the workpiece according to a conveyance position by the conveyance device and a position of the surface treatment device.

2. The surface treatment apparatus according to claim 1, wherein
the first adjustment device adjusts the orientation of the workpiece around an axis orthogonal to both a conveyance direction of the conveyance device and a normal direction of an electrode included in the surface treatment device.

3. The surface treatment apparatus according to claim 1, wherein
the first adjustment device adjusts the orientation of the workpiece around a normal direction of the workpiece.

4. The surface treatment apparatus according to claim 1, further comprising:
a measurement device that measures distortion in a height direction of the workpiece before the surface treatment device performs surface treatment; and
a second adjustment device that adjusts an inclination in the height direction of the workpiece to a predetermined value based on the distortion measured by the measurement device.

5. The surface treatment apparatus according to claim 4, wherein
the measurement device
measures the distortion in the height direction of the workpiece based on distances between the measurement device and the workpiece measured at a plurality of different positions in the height direction of the workpiece.

6. The surface treatment apparatus according to claim 1, wherein
the mounting device includes:
a pedestal member that is conveyed by the conveyance device;
a base member that is installed on the pedestal member and fixes the workpiece; and
a support member that supports the workpiece on the base member.

7. The surface treatment apparatus according to claim 1, wherein
a width of an electrode included in the surface treatment device along a conveyance direction of the conveyance device is smaller than a width of the workpiece along the conveyance direction of the conveyance device.

8. The surface treatment apparatus according to claim 1, wherein
the surface treatment device is installed to face both surfaces of the workpiece.

9. The surface treatment apparatus according to claim 1, wherein
the surface treatment device is
a plasma generation apparatus that performs surface treatment of the workpiece by irradiating the workpiece with plasma.

10. The surface treatment apparatus according to claim 1, wherein
the surface treatment device is
a sputtering apparatus that performs sputtering on the workpiece.

11. The surface treatment apparatus according to claim 1, further comprising
a shielding member that blocks a surface treatment device other than one of a plurality of surface treatment devices when it performs surface treatment on the workpiece.

12. A surface treatment method comprising
performing surface treatment while conveying a mounting device on which a workpiece is mounted, along a surface treatment device that performs the surface treatment on the workpiece, and adjusting an orientation of the workpiece according to a conveyance position of the workpiece and a position of the surface treatment device, the mounting device being housed in a housing unit including the surface treatment device.
